(19) United States
(12) Patent Application Publication
(10) Pub. No.: US 2013/0140502 A1
(43) Pub. Date: Jun. 6, 2013

(54) SPUTTERING TARGET

(71) Applicants: Shigekazu Tomai, Sodegaura-shi (JP); Kazuaki Ebata, Sodegaura-shi (JP); Shigeo Matsuzaki, Sodegaura-shi (JP); Koki Yano, Sodegaura-shi (JP)

(72) Inventors: Shigekazu Tomai, Sodegaura-shi (JP); Kazuaki Ebata, Sodegaura-shi (JP); Shigeo Matsuzaki, Sodegaura-shi (JP); Koki Yano, Sodegaura-shi (JP)

(73) Assignee: IDEMITSU KOSAN CO.,LTD

(21) Appl. No.: 13/700,789

(22) PCT Filed: Jun. 1, 2011
(86) PCT No.: PCT/JP2011/003087

§ 371 Date: Feb. 21, 2013

(30) Foreign Application Priority Data
Feb. 6, 2010 (JP) 2010-126497

(51) Int. Cl. H01L 49/02; C23C 14/08

(52) U.S. Cl. CPC H01L 49/02; C23C 14/086
USPC 252/518.1; 204/298.13; 264/648

(57) ABSTRACT

An oxide sintered body including an oxide of indium (In), gallium (Ga), and positive trivalent and/or positive tetravalent metal X, wherein the amount of the metal X relative to the total amount of In and Ga is 100 to 10000 ppm (weight).

### TECHNICAL FIELD

The invention relates to an oxide sintered body, a sputtering target formed thereof, an oxide thin film produced by using the target, and an oxide semiconductor device comprising the oxide thin film.

### BACKGROUND ART

In recent years, remarkable progress has been attained in displays. Various displays such as liquid crystal displays and EL displays have been actively incorporated in an OA apparatus such as a PC and a word processor. Each of these displays has a sandwich structure in which a display element is disposed between transparent conductive films.

Currently, a silicon-based semiconductor film has been used mainly as a switching device to drive the above-mentioned display. The reason therefor is that, in addition to improved stability and processibility of a silicon-based thin film, a thin film transistor using a silicon-based thin film has advantages such as a high switching speed. Generally, this silicon-based thin film is fabricated by the chemical vapor deposition (CVD) method.

However, in the case of an amorphous silicon-based thin film, there are disadvantages that the switching speed is relatively low and images cannot be displayed when a high-speed animation or the like are displayed. Further, in the case of a crystalline silicon-based thin film, although the switching speed is relatively high, heating at a high temperature of 800° C. or higher, heating by means of a laser or the like is required, and hence, a large amount of energy and a large number of steps are required in production. Although a silicon-based thin film exhibits superior performance as a voltage element, it encounters a problem that its properties change with the passage of time when current is flown.

Under such circumstances, other films than silicon-based thin films have been studied. As the transparent semiconductor film which is superior to the silicon-based thin films in stability and has a light transmittance equivalent to that of an ITO (indium tin oxide) film, and as a target to obtain the same, a transparent semiconductor thin film comprising indium oxide, gallium oxide and zinc oxide or a transparent semiconductor thin film comprising zinc oxide and magnesium oxide has been proposed (see Patent Document 1).

### RELATED ART DOCUMENT

### Patent Document

Patent Document 1: JP-A-2004-149883

### SUMMARY OF THE INVENTION

An object of the invention is to provide a non-silicon-based semiconductor thin film which can be used in an oxide semiconductor device and an oxide sintered body and a sputtering target for forming the same. An object of the invention is to provide an oxide semiconductor device using a novel non-silicon-based semiconductor thin film.

According to the invention, the following oxide sintered body or the like are provided.

1. An oxide sintered body comprising an oxide of indium (In), gallium (Ga), and positive trivalent and/or positive tetravalent metal X, wherein

the amount of the metal X relative to the total amount of In and Ga is 100 to 10000 ppm (weight).

2. The oxide sintered body according to 1, wherein the metal X is one or more selected from Sn, Zr, Ti, Ge and Hf.
3. The oxide sintered body according to 1 or 2, wherein the metal X comprises Sn.
4. The oxide sintered body according to any of 1 to 3, wherein an atomic ratio Ga/(Ga+In) is 0.005 to 0.15.
5. The oxide sintered body according to any of 1 to 4, wherein the bulk resistivity is 10 mΩcm or less.
6. The oxide sintered body according to any of 1 to 5, wherein the particle size of dispersed gallium is 1 μm or less.
7. The oxide sintered body according to any of 1 to 6, wherein gallium and metal X are dispersed in the solid-solution state in the bixbyite structure of In₂O₃.
8. A method for producing the oxide sintered body according to any of 1 to 7, comprising the steps of:

mixing indium compound powder having an average particle size of less than 2 μm, gallium compound powder having an average particle size of less than 2 μm and metal X compound powder having an average particle size of less than 2 μm such that the atomic ratio Ga/(In+Ga) becomes 0.001 to 0.10 and the amount of the metal X relative to the total amount of In and Ga becomes 100 to 10000 ppm;

shaping the mixture to prepare a shaped body; and

firing the shaped body at 1200 to 1600° C. for 2 to 96 hours.

9. The method for producing an oxide sintered body according to 8, wherein the firing is conducted in the atmosphere of oxygen or under pressure.
10. A sputtering target comprising the oxide sintered body according to any of 1 to 7.
11. An oxide thin film which is formed by using the sputtering target according to 10.
12. An oxide thin film comprising an oxide of indium (In), gallium (Ga) and positive trivalent and/or positive tetravalent metal X, wherein the amount of the metal X relative to the total amount of In and Ga is 100 to 10000 ppm (weight).
13. An oxide semiconductor device wherein an active layer comprises the oxide thin film according to 11 or 12.

According to the invention is to provide a non-silicon-based semiconductor thin film which can be used in an oxide semiconductor device and an oxide sintered body and a sputtering target for forming the same. According to the invention, an oxide semiconductor device using a novel non-silicon-based semiconductor thin film can be provided.

### BRIEF DESCRIPTION OF THE DRAWINGS

FIG. 1 is a view showing the chart obtained by the X-ray diffraction in Example 2;

FIG. 2 is a view showing the chart obtained by the X-ray diffraction in Example 3;

FIG. 3 is a view showing the results of observation by means of an EPMA (electron probe microanalyzer); and

FIG. 4 is a view showing the chart obtained by the X-ray diffraction in Comparative Example 1.

### MODE FOR CARRYING OUT THE INVENTION

The oxide sintered body of the invention comprises an oxide of indium (In), gallium (Ga) and positive trivalent and/or positive tetravalent metal X. The amount of X relative to the total amount of In and Ga (hereinafter referred to as the “X/(In+Ga)”) is 100 to 10000 ppm (weight).

The metal X is preferably one or more elements selected from Sn, Zr, Ti, Ge and Hf. It is preferred that the metal X at least contain Sn.

The atomic ratio Ga/(In +Ga) is preferably 0.001 to 0.15.

If the atomic ratio Ga/(In +Ga) is less than 0.001, variations in lattice constant of indium oxide crystals may be decreased. As a result, effects of adding gallium may not be exhibited. If the atomic ratio exceeds 0.15, InGaO₃ or the like may be deposited. If the amount of deposited InGaO₃ or the like is large, the electric resistance of a target is increased, whereby production by DC sputtering excellent in productivity may become difficult.

It is preferred that Ga/(In+Ga) be 0.005 to 0.15, more preferably Ga/(In+Ga) be 0.01 to 0.12, and further preferably Ga/(In+Ga) be 0.03 to 0.10.

If/(In+Ga) is less than 100 ppm, the electric resistance of the target is increased. If X/(In+Ga) exceeds 10,000 ppm, the resistance of the oxide semiconductor cannot be controlled.

It is preferred that the oxide sintered body of the invention be substantially composed of an oxide of indium, gallium and metal X. It is preferred that silicon be not contained.

In the invention, the “substantially” means that the effects as the oxide sintered body are derived from the above-mentioned composition or that 95 wt % or more and 100 wt % or less (preferably 98 wt % or more and 100 wt % or less) of the oxide sintered body is an oxide of indium, gallium and metal X.

As mentioned above, the oxide sintered body of the invention substantially comprises an oxide of indium, gallium and metal X. In an amount range which does not impair the advantageous effects of the invention, other impurities which have been inevitably mixed in may be contained.

In the oxide sintered body of the invention, it is preferred that Ga and metal X be dispersed in a solid-solution state in the bixbyite structure of In₂O₃. Ga is dispersed normally in the solid-solution state in the In site. Part of Ga₂O₃ may remain, which causes cracks or the like during the production of the sintered body. By adding a trace amount of element X (X is one or more selected from Sn, Zr, Ge and Ti), presence of Ga₂O₃ can be prevented. Further, since thermal conductivity is also improved, a large-sized sintered body does not break easily when bonding to a backing plate.

The density of the oxide sintered body of the invention is preferably 6.5 to 7.2 g/cm³. If the density is small, the surface of the sputtering target formed of an oxide sintered body is blackened, and as a result, abnormal discharge is induced, whereby the sputtering speed may be lowered.

In order to increase the density of the sintered body, it is preferable to use a raw material having a particle size of 10 μm or less and to mix the raw material powders uniformly. If the particle size is large, the reaction of an indium compound and a gallium compound may not proceed. Similarly, as in the case where the raw material powders are not uniformly mixed, since particles which remain un-reacted or particles which have grown extraordinary are present, the density may not increase.

In the oxide sintered body of the invention, normally, Ga is dispersed in indium oxide. It is preferred that the diameter of the aggregate of Ga atoms which are dispersed be 1 μm or less. The dispersion as referred to herein means a case in which gallium ions are in the solid-solution state in indium oxide crystals or a case in which Ga compound particles are finely dispersed in indium oxide particle. Due to the fine dispersion of Ga, sputtering discharge can be conducted stably. The diameter of the Ga aggregate can be measured by means of an EPMA (electron probe microanalyzer).

The bulk resistivity of the oxide sintered body of the invention is preferably 10 mΩcm or less. If Ga₂O₃ or the like are observed due to insufficient solid solution of Ga, abnormal discharge may occur. More preferably, the bulk resistivity is 5 mΩ·cm or less. Although there are no lower restrictions on the bulk resistivity, it is not necessary to allow it to be less than 1 mΩcm.

The oxide sintered body of the invention comprises trivalent and/or tetravalent metal X in an amount of 100 to 10000 ppm relative to the amount of In and Ga. Due to the presence of trivalent and/or tetravalent metal, the resistance of the sintered body can be suppressed low. Of these, tin is preferable. The concentration thereof is preferably 100 ppm to 5000 ppm.

The atomic ratio of metal X to indium metal is preferably X/(In+Ga)=200 to 5000 ppm. More preferably, X/(In+Ga)=300 to 3000 ppm, and further preferably X/(In +Ga)=500 to 1000 ppm.

The method for producing the oxide sintered body of the invention comprises the steps of:

mixing indium compound powder having an average particle size of less than 2 μm, gallium compound powder having an average particle size of less than 2 μm and metal X compound having an average particle size of less than 2 μm such that the atomic ratio Ga/(In +Ga) becomes 0.001 to 0.10 and the amount of the metal X relative to the total amount of In and Ga becomes 100 to 10000 ppm;

shaping the mixture to prepare a shaped body; and

firing the shaped body at 1200 to 1600° C. for 2 to 96 hours.

In the meantime, the average particle size is measured by the method according to JIS R 1619.

In the step where the raw material compound powders are mixed, the indium compound, the gallium compound and the compound of the metal X used as the raw material powders may be an oxide or one which becomes an oxide after firing (a precursor of an oxide). As examples of the indium oxide precursor and the oxide precursor of the metal X, sulfide, sulfate, nitrate, halide (chloride, bromide or the like), carbonate, an organic acid salt (acetate, propionate, naphthenate or the like), an alkoxide (methoxide, ethoxide or the like), an organic metal complex (acetyl acetonate) or the like of indium or metal X can be given.

Of these, in order to attain complete thermal decomposition at lower temperatures to allow no impurities to remain, nitrate, an organic acid salt, an alkoxide or an organic metal complex are preferable. In the meantime, it is the best way to use an oxide of each metal.

The purity of the above-mentioned each raw material is normally 99.9 mass % (3N) or more, preferably 99.99 mass % (4N) or more, further preferably 99.995 mass % or more, with 99.999 mass % (5N) or more being particularly preferable. If the purity of each material is 99.9 mass % (3N) or more, reliability can be sufficiently retained without deterioration of semiconductor properties due to the presence of impurities such as a tetravalent or larger metal other than metal X, Fe, Ni, Cu or the like. In particular, a content of Na, K and Ca of 100 ppm or less is preferable since electric resistance does not deteriorate with the passage of time when a thin film is fabricated.

It is preferable to conduct mixing by (i) a solution (co-precipitation) method or (ii) a physical mixing method. A physical mixing method is preferable in order to decrease the cost.

In the physical mixing method, a raw material powder containing the indium compound, the gallium compound and the compound of the metal X as mentioned above are put in a mixer such as a ball mill, a jet mill, a pearl mill, a beads mill or the like, followed by uniform mixing.

It is preferred that the mixing time be 1 to 200 hours. If the mixing time is less than 1 hour, the uniformity of dispersed elements may be insufficient. A mixing time exceeding 200 hours is too long a time, leading to poor productivity. A mixing time of 10 to 60 hours is particularly preferable.

As a result of mixing, it is preferred that the average particle size of the resulting raw material mixture powder be 0.01 to 1.0 μm. If the particle size is less than 0.01 μm, powder tends to be aggregated easily, resulting in poor handling properties. Further, a dense sintered body may not be obtained. On the other hand, if the particle size exceeds 1.0 μm, a dense sintered body may not be obtained.

The method of the invention may further contain a step in which the resulting mixture after the mixing of the raw material powder is subjected to pre-firing. By conducting pre-firing, the density of the resulting sputtering target can be increased.

In the pre-firing step, it is preferable to subject the mixture obtained in the step (a) to a heat treatment preferably at a temperature of 200 to 1000° C. for 1 to 100 hours, more preferably 2 to 50 hours. By a heat treatment at 200° C. or more and for 1 hour or more, thermal decomposition of the raw material compound can be conducted sufficiently. If the heat treatment is conducted at 1000° C. or less and for 100 hours or shorter, there is no fear that the particles are agglomerated.

Further, it is preferred that the pre-fired mixture obtained in this step be pulverized before the subsequent shaping and the sintering steps. Pulverization of the pre-fired mixture is suitably conducted by means of a ball mill, a roll mill, a pearl mill, a jet mill or the like. The average particle diameter of the pre-fired mixture obtained after pulverization is 0.01 to 3.0 μm, preferably 0.1 to 2.0 μm. If the average particle diameter of the pre-fired mixture after pulverization is 0.01 μm or more, it is possible to retain sufficient bulk density, and handling becomes easy. Further, if the average particle diameter of the pre-fired mixture after pulverization is 3.0 μm or less, the density of the sputtering target finally obtained can be easily increased. Further, the average particle diameter of the raw material powder can be measured according to the method described in JIS R 1619.

The mixed raw material powders are shaped by a known method, such as pressure shaping, cold isostatic pressing or the like.

As the pressure shaping, a known method such as cold pressing, hot pressing or the like can be used. For example, the resulting mixture powder is filled in a mold, and the powder is then subjected to pressure shaping by means of a cold pressing machine. Pressure shaping is conducted at normal temperature (25° C.) at 100 to 100,000 kg/cm², for example.

By firing the shaped body of the raw material powder, an oxide sintered body is produced.

The sintering temperature is 1200 to 1600° C., preferably 1250 to 1580° C., with 1300 to 1550° C. being particularly preferable.

Within the above-mentioned range of the sintering temperature, gallium tends to be in the solid-solution state easily in indium oxide, whereby bulk resistivity can be decreased. Further, by allowing the sintering temperature to be 1600° C. or less, evaporation of Ga or Sn can be suppressed.

Sintering time is 2 to 96 hours, preferably 10 to 72 hours.

By allowing the sintering time to be 2 hours or more, it is possible to improve the sintering density the resulting oxide sintered body and to enable the processing of the surface. Further, by allowing the sintering time to be 6 hours or less, sintering can be conducted within a suitable period of time.

Sintering is preferably conducted in an atmosphere of an oxygen gas. By conducting sintering in an oxygen gas atmosphere, it is possible to improve the density of the resulting oxide sintered body, and occurrence of abnormal discharge of the oxide sintered body at the time of sputtering can be suppressed. As for oxygen atmosphere, it suffices that the oxygen gas concentration be 10 to 100 vol %, for example. However, sintering may be conducted in a non-oxidizing atmosphere (for example, vacuum or nitrogen atmosphere).

Further, sintering may be conducted in an atmosphere or under pressure. The pressure is 9800 to 1000000 Pa, preferably 100000 to 500000 Pa.

The oxide sintered body of the invention can be produced by the above-mentioned method. The oxide sintered body of the invention can be used as a sputtering target. Since the oxide sintered body of the invention has a high conductivity, when it is used as a sputtering target, it is possible to use the DC sputtering method by which a film can be formed at a high film-forming speed.

As for the sputtering target of the invention, in addition to the above-mentioned DC sputtering method, any of the RF sputtering method, the AC sputtering method, the pulse DC sputtering method or the like can be applied, and sputtering free from abnormal discharge is possible.

An oxide thin film can be formed by the deposition method, the sputtering method, the ion plating method, the pulse laser deposition method or the like by using the above-mentioned oxide sintered body. As the sputtering method, the RF magnetron sputtering method, the DC magnetron sputtering method, the AC magnetron sputtering method, the pulse DC magnetron sputtering method or the like can be given.

As the sputtering gas, a mixed gas of an inert gas such as argon and a reactive gas such as oxygen, water and hydrogen can be used. Although the partial pressure of the reactive gas at the time of sputtering differs depending on the method of discharge or power, it is preferable to render the partial pressure to be about 0.1% or more and 20% or less. If the partial pressure is less than 0.1%, the transparent amorphous film immediately after the film formation has conductivity, and is difficult to be used as an oxide semiconductor. On the other hand, if the partial pressure exceeds 20%, the transparent amorphous film becomes an insulator, leading to difficulty in use as an oxide semiconductor. The partial pressure is preferably 1 to 10%.

The oxide thin film of the invention is formed by using the above-mentioned sputtering target of the invention.

Further, the oxide thin film of the invention comprises an oxide of indium (In), gallium (Ga), and positive trivalent or positive tetravalent metal X, and has an atomic ratio X/(In +Ga) of 100 to 10000 ppm. The atomic ratio Ga/(In +Ga) is preferably 0.005 to 0.08. It is preferred that the oxide thin film be essentially composed of an oxide of indium, gallium, and metal X and do not contain silicon.

The metal X is preferably one or more selected from Sn, Zr, Ti, Ge and Hf. It is preferred that the oxide thin film of the invention have a bixbyite structure of In₂O₃ in which gallium is in the solid-solution state in indium oxide and have an atomic ratio of Ga/(In +Ga) of 0.001 to 0.15.

Gallium has an effect of decreasing the lattice constant of indium oxide, and hence has an effect of increasing the mobility. Further, gallium has strong bonding power with oxygen, and hence has an effect of decreasing the amount of oxygen deficiency of a polycrystallized indium oxide thin film. Gallium has an area which is completely in the solid-solution state with indium oxide, and hence, it is completely integrated with crystallized indium oxide to decrease the lattice constant. If gallium is added in an amount which exceeds the solubility limit, deposited gallium oxide may cause electrons to be scattered and may hinder crystallization of indium oxide.

Further, the element X to be added has an effect of increasing the thermal conductivity of the target. Therefore, when a large-sized sintered body improved in productivity is bonded, cracking or the like can be prevented.

If the ratio Ga/(Ga+In) exceeds 0.10, the thermal conductivity of the target significantly is decreased. However, such a decrease can be prevented by adding X.

The oxide thin film of the invention normally comprises a single phase of a bixbyite structure. As for the lattice constant of the bixbyite structure, although the lower limit thereof is not particularly restricted, but preferably 10.01 Å or more and less than 10.118 Å. A low lattice constant means that the metal-to-metal distance is short due to the shrinkage of the crystal lattice. Due to the narrowing of the metal-to-metal distance, the speed of electrons moving on the metal orbit is increased, whereby the mobility of the resulting thin film transistor is increased. If the lattice constant of the bixbyite structure is too large, it will be equal to the lattice constant of indium oxide itself, and as a result, mobility is not increased.

As for the oxide thin film of the invention, it is preferred that the diameter of the aggregate of dispersed Ga atoms be less than 1 μm.

The oxide thin film of the invention can be used as an active layer of an oxide semiconductor device. As examples of an oxide semiconductor device, a thin film transistor, a power transistor, a phase change memory or the like can be given.

The oxide thin film of the invention can preferably be used in a thin film transistor. In particular, it can be used as a channel layer. An oxide thin film can be used as it is or after being subjected to a heat treatment.

The thin film transistor may be of a channel etch type. The thin film of the invention is crystalline and has durability. Therefore, in the production of a thin film transistor using the thin film of the invention, a photolithographic process in which a metal thin film such as Al is etched to form source/drain electrodes and a channel part becomes possible.

The thin film transistor may be of an etch stopper type. In the thin film of the invention, since an etch stopper can protect a channel part formed of a semiconductor layer, and a large amount of oxygen can be incorporated into a semiconductor film at the time of film formation, there is no need to supply oxygen from the outside through an etch stopper layer. Further, since the film is still amorphous immediately after the film formation, it is possible to etch a thin film of a metal such as Al to form source/drain electrodes and a channel part, and also possible to etch a semiconductor layer to shorten the photolithographic process.

The thin film transistor may be either of top contact type or of bottom contact type. However, if the thin film transistor is of bottom contact type, due to the presence of moisture adhered to the source/drain electrodes or an oxide film, contact resistance may be generated easily in the interface with an oxide semiconductor. By removing them by reverse sputtering or vacuum heating before film formation by the oxide semiconductor sputtering, contact resistance is decreased, whereby an excellent transistor tends to be obtained easily.

The method for producing a thin film transistor comprises the steps of forming an oxide thin film by using the sputtering target of the invention; subjecting the oxide thin film to a heat treatment in an oxygen atmosphere, and forming an oxide insulator layer on the heat-treated oxide thin film. Crystallization is conducted by a heat treatment.

In the thin film transistor, it is preferred that an oxide insulator layer be formed on the heat-treated oxide thin film in order to prevent deterioration of semiconductor properties with the passage of time.

It is preferred that an oxide thin film be formed in a film-forming gas having an oxygen content of 10 vol % or more. As the film-forming gas, a mixed gas of argon and oxygen or a mixed gas of argon and water vapor is used.

By allowing the oxygen concentration in the film-forming gas to be 10 vol % or more or by allowing the water vapor concentration in the film-forming gas to be 1 vol % or more, subsequent crystallization can be stabilized.

In particular, introduction of water vapor during the film formation is effective in order to obtain good transistor properties. If water vapor is introduced in plasma, an OH radical (OH.) having strong oxidizing power is generated, and as a result, indium oxide can be oxidized efficiently as follows, for example.

In₂O₃+2×OH.→In₂O₃+xH₂O

Although an oxidizing reaction proceeds only in an oxygen gas, oxygen deficiency tends to remain. If a large amount of oxygen deficiency remains, oxygen deficiency works as a trap or a donor in the vicinity of a conductor, whereby an on/off ratio may be lowered or an S-value may be decreased.

Further, in order to allow an OH. to be scattered uniformly in the entire substrate during the sputtering, scattering manner of plasma is also important. In particular, if the size of a substrate is large, by decreasing the speed of swinging of the magnet at the end part thereof, it is possible to ensure the uniformity. The concentration of the water introduced during the sputtering differs depending on the sputtering apparatus or the production conditions, and hence, the water concentration cannot be simply determined. However, it depends on how the plasma is scattered, the manner of discharge, the film-forming speed, the substrate-target distance or the like.

Further, hydrogen and oxygen may be simultaneously introduced instead of water. However, if the amount of oxygen is insufficient, the effects of reduction by hydrogen plasma become significant. Therefore, it is required that oxygen be introduced in an amount ratio of 1:2 or more. In this case, control of concentration of OH. is important.

For the crystallization step of the oxide thin film, in the presence or absence of oxygen, a lamp annealing apparatus, a laser annealing apparatus, a heat plasma apparatus, a hot air heating apparatus, a contact heating apparatus or the like can be used.

The heating rate is normally 40° C./min or more, preferably 70° C./min or more, more preferably 80° C./min or more, with 100° C./min or more being further preferable. There are no upper limits on the heating rate. In the case of heating by laser heating and heat plasma, it is possible to increase the temperature instantly to a desired heat processing temperature.

A higher cooling rate is preferable. However, if the cooling speed is too large, the substrate may be cracked, and electric properties may be lowered due to the internal stress remaining in the thin film. If the cooling rate is too slow, crystals may be grown extraordinary by the annealing effect. Therefore, as in the case of the heating rate, it is preferable to set the cooling rate. The cooling rate is normally 5 to 300° C./min, more preferably 10 to 200° C./min, with 20 to 100° C./min being further preferable.

The heat treatment of the oxide thin film is preferable 250 to 500° C. for 0.5 to 1200 minutes. If the heat treatment temperature is less than 250° C., crystallization may not be attained, and if the heat treatment temperature exceeds 500° C., damage may be exerted on the substrate or the semiconductor film. If the heat treatment time is less than 0.5 min, the heat treatment time is too short, and therefore, crystallization may not be attained. If the heat treatment time is 1200 minutes, it takes a too long period of time.

### EXAMPLES

Subsequently, the invention will be explained with reference to the examples and the comparative examples. However, the examples are intended to indicate a preferred but the invention are not limited thereto. Therefore, modifications based on the technical concept of the invention or other examples are included in the scope of the invention.

### Examples 1 to 8

As the raw material powder, the following oxide powder was used. The average particle diameter was measured by means of a laser diffraction particle distribution measurement apparatus (SALD-300V, manufactured by Shimadzu Corporation), and the specific surface area was measured by the BET method.

(a) Indium oxide powder: Specific surface area 6 m²/g, average particle size 1.2 μm
(b) Gallium oxide powder: Specific surface area 6 m²/g, average particle size 1.5 μm
(c) Tin oxide powder: Specific surface area 6 m²/g, average particle size 1.5 μm
(d) Zirconium oxide powder: Specific surface area 6 m²/g, average particle size 1.5 μm
(e) Titanium oxide powder: Specific surface area 6 m²/g, average particle size 1.5 μm
(f) Germanium oxide powder: Specific surface area 6 m²/g, average particle size 1.5 μm

The specific surface area of the total raw material mixture powder composed of (a) and (b) was 6.0 m²/g.

The above-mentioned powder was weighed such that the Ga/(In +Ga) ratio and X/(In +Ga) shown in Table 1 were attained. Then, the powder was mixed and pulverized by means of a wet media mixing mill. As the pulverization medium, zirconium beads with a diameter of 1 mm were used. During the pulverizing process, by confirming the specific surface area of the mixed powder, the specific surface area of the mixed powder was increased by 2 m²/g from the specific surface area of the raw material mixed powder.

After pulverization, the mixture powder obtained by drying by means of a spray dryer was filled in a mold (350 mm in diameter and 20 mm in thickness), and was subjected to press shaping by means of a cold pressing machine. After shaping, while circulating oxygen, sintering was conducted at a temperature shown in Table 1 for 20 hours in the atmosphere of oxygen, whereby a sintered body was produced.

The density of the sintered body thus produced was calculated from the weight and the outer dimension of the sintered body which had been cut into a size of 200 mmφ×10 mm. In this way, a sintered body for a sputtering target having a high sintered body density could be obtained without conducting a pre-firing step.

The bulk resistivity (conductivity) (mΩcm) of this sintered body was measured by means of a resistivity meter (Loresta manufactured by Mitsubishi Chemical Analytic Co., Ltd.) by the four probe method.

The elemental composition ratio (atomic ratio) of this sintered body was measured by means of an inductively coupled plasma atomic emission spectrometer (ICP-AES). The atomic ratio of the sintered body was in correspondence with the atomic ratio of the raw material. The results are shown in Table 1.

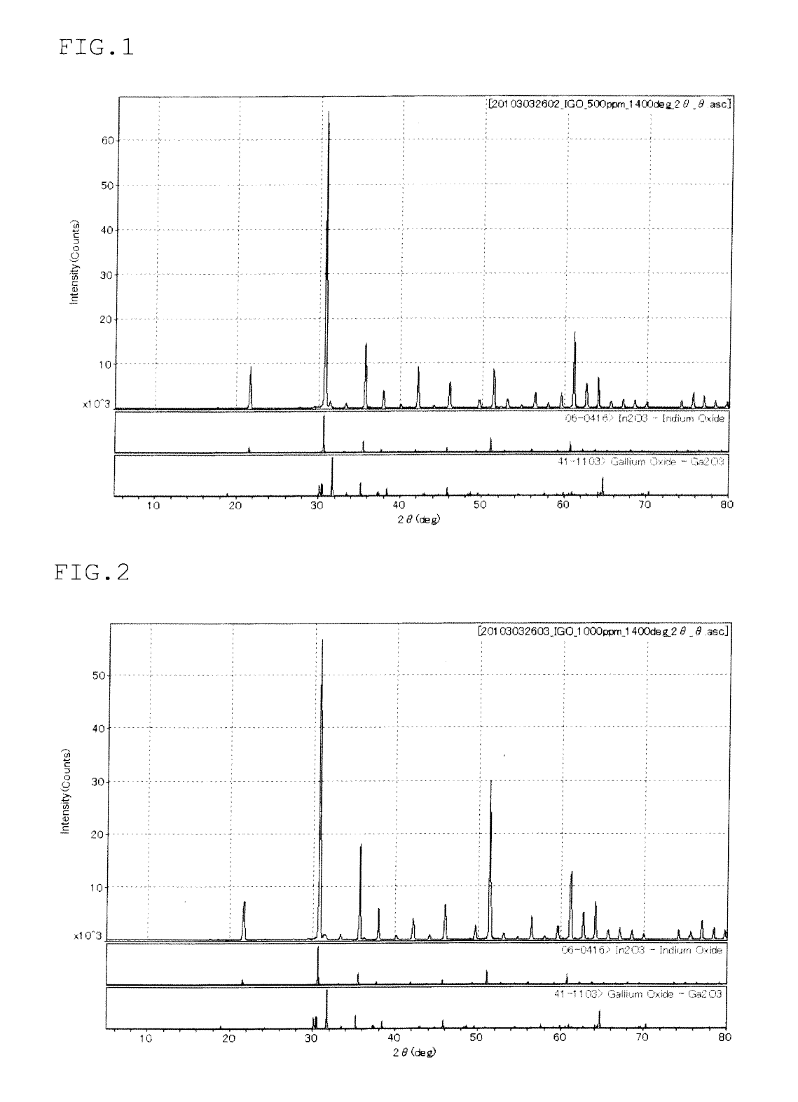

For the resulting sintered body, an X-ray analysis was conducted. FIGS. 1 and 2 show X-ray charts of Examples 2 and 3.

As a result of analyzing the chart, the bixbyite structure of In₂O₃ was observed in the sintered bodies of Examples 2 and 3. Almost no Ga₂O₃ structure could be observed.

As a result of the observation of the sintered body prepared in Example 2 by means of an EPMA, it was confirmed that Ga was in the solid-solution state in In₂O₃, and that the diameter of Ga was 1 μm or less.

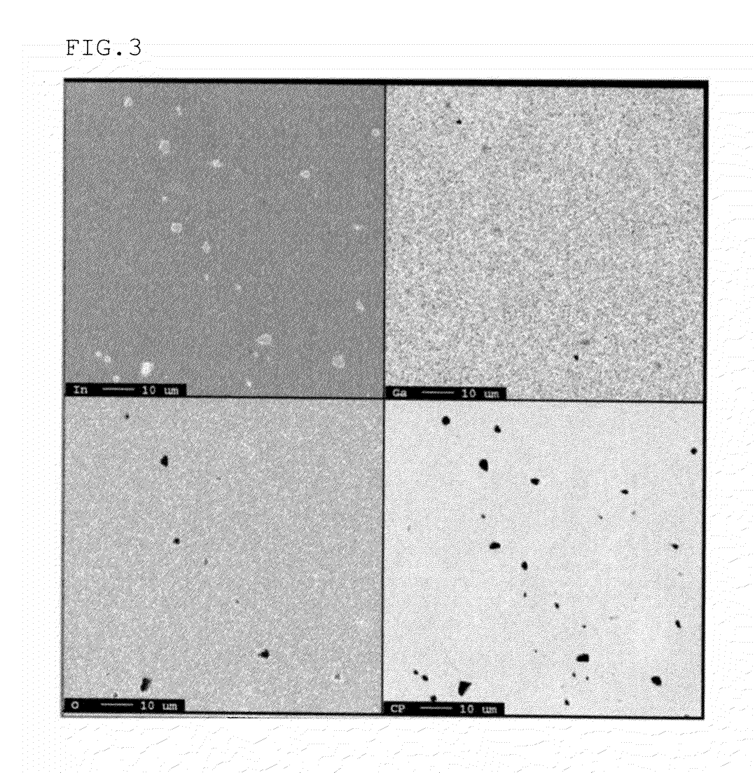

FIG. 3 shows the results of the EPMA observation. From FIG. 3, it can be understood that Ga is uniformly in the solid-solution state in In₂O₃. In the upper right image of FIG. 3, Ga₂O₃ could be partially observed, but the diameter thereof was 1 μm or less.

The resulting sintered body was laminated to a backing plate, whereby a sputtering target having a diameter of 200 mmφ was obtained. Lamination was conducted as follows. A copper-made backing plate was provided on a hot plate, and an indium wire of 0.2 mm in length was put thereon. The sintered body was mounted thereon. Thereafter, the hot plate was heated to 250° C. to allow indium to be fused, whereby a sputtering target was obtained.

On a conductive silicon substrate provided with a 100 nm-thick thermally oxidized film (SiO₂ film) and on a quartz substrate, a 50 nm-thick semiconductor film was respectively formed by using the targets obtained in Examples 1 to 8 under the conditions shown in Table 1 (as-depo). XRD (X-ray diffraction) of the thus obtained thin films was measured, and as a result, all of the thin films were amorphous.

Subsequently, a metal mask was provided, whereby a channel part having a length of 200 μm and a width of 1000 μm was formed, and source/drain electrodes were formed by depositing gold.

The device was subjected to annealing in a heating furnace which was heated to 300° C. in the air for 1 hour, and then XRD (X-ray diffraction) of the channel part was measured. It was found that the entire channel part had been crystallized.

The properties of the resulting transistor were measured. As a result, it was found that the transistor exhibited excellent transistor properties in each of Examples 1 to 8, as shown in Table 1.

TABLE 1

| | | Examples | | | |
|---|---|---|---|---|---|
| | | 1 | 2 | 3 | 4 |
| Composition of | Composition | In—Ga—Sn—O | In—Ga—Sn—O | In—Ga—Sn—O | In—Ga—Sn—O |
| sintered body | Composition ratio | In: 99.5 | In: 95 | In: 95 | In: 85 |
| | (%) | Ga: 0.5 | Ga: 5 | Ga: 5 | Ga: 15 |
| | X/(In + Ga) | Sn: 100 ppm | Sn: 500 ppm | Sn: | Sn: |
| | | | | 1000 ppm | 10000 ppm |
| Firing | Temperature | 1400 | 1400 | 1400 | 1400 |
| | (° C.) | | | | |
| | Time (h) | 20 | 20 | 20 | 20 |
| Evaluation of | Bulk resistivity | 8 | 9 | 8 | 10 |
| target | (mΩ · cm) | | | | |
| | Density (cm⁻³) | 6.8 | 6.5 | 6.3 | 6 |
| | Occurrence of | None | None | None | None |
| | cracks | | | | |
| Sputtering | Ultimate pressure | 1.00E−04 | 1.00E−04 | 1.00E−04 | 1.00E−04 |
| conditions | (Pa) | | | | |
| | Sputtering | 0.4 | 0.4 | 0.4 | 0.1 |
| | pressure (Pa) | | | | |
| | Introduction gas | Ar, O₂ | Ar, H₂O | Ar, H₂O, O₂ | Ar, O₂ |
| | Introduction ratio | 98:2 | 98:2 | 90:5:5 | 98:2 |
| | Power | DC100 W | DC100 W | DC100 W | DC100 W |
| XRD | as-depo | Amorphous | Amorphous | Amorphous | Amorphous |
| | Annealing | 300° C. × 1 h | 300° C. × 1 h | 300° C. × 1 h | 300° C. × 1 h |
| | After annealing | Crystalline | Crystalline | Crystalline | Crystalline |
| FET | Mobility (cm²/Vs) | 50 | 60 | 60 | 50 |
| performance | Vth (V) | 0.5 | −2 | 5 | 0.5 |
| | S value (V/dec) | 0.5 | 0.5 | 1.5 | 1.5 |
| | | Examples | | | |
| | | 5 | 6 | 7 | 8 |
| Composition of | Composition | In—Ga—Zr—O | In—Ga—Ti—O | In—Ga—Ge—O | In—Ga—Sn—O |
| sintered body | Composition ratio | In: 99.5 | In: 95 | In: 90 | In: 85 |
| | (%) | Ga: 0.5 | Ga: 5 | Ga: 10 | Ga: 15 |
| | X/(In + Ga) | Zr: | Sn: 100 ppm | Ge: | Sn: |
| | | 500 ppm | Ti: 100 ppm | 10000 ppm | 100 ppm |
| Firing | Temperature | 1400 | 1400 | 1400 | 1400 |
| | (° C.) | | | | |
| | Time (h) | 20 | 20 | 20 | 20 |
| Evaluation of | Bulk resistivity | 8 | 4 | 8 | 20 |
| target | (mΩ · cm) | | | | |
| | Density (cm⁻³) | 6.8 | 6.9 | 6.3 | 6 |
| | Occurrence of | None | None | None | None |
| | cracks | | | | |
| Sputtering | Ultimate pressure | 1.00E−04 | 1.00E−04 | 1.00E−04 | 1.00E−04 |
| conditions | (Pa) | | | | |
| | Sputtering | 0.4 | 0.4 | 0.4 | 0.1 |
| | pressure (Pa) | | | | |
| | Introduction gas | Ar, O₂ | Ar, H₂O | Ar, H₂O, O₂ | Ar, H₂O |
| | Introduction ratio | 98:2 | 98:2 | 90:5:5 | 98:2 |
| | Power | DC100 W | DC100 W | DC100 W | DC100 W |
| XRD | as-depo | Amorphous | Amorphous | Amorphous | Amorphous |
| | Annealing | 300° C. × 1 h | 300° C. × 1 h | 300° C. × 1 h | 300° C. × 1 h |
| | After annealing | Crystalline | Crystalline | Crystalline | Crystalline |
| FET | Mobility (cm²/Vs) | 50 | 60 | 60 | 50 |
| performance | Vth (V) | 0.5 | −2 | 5 | 0.5 |
| | S value (V/dec) | 0.5 | 0.5 | 1.5 | 1.5 |

### Comparative Examples 1 to 3

Sintered bodies were produced and evaluated in the same manner as in Example 1, except that the raw material powders were mixed in an amount ratio shown in Table 2 and sintering was conducted. The results are shown in Table 2.

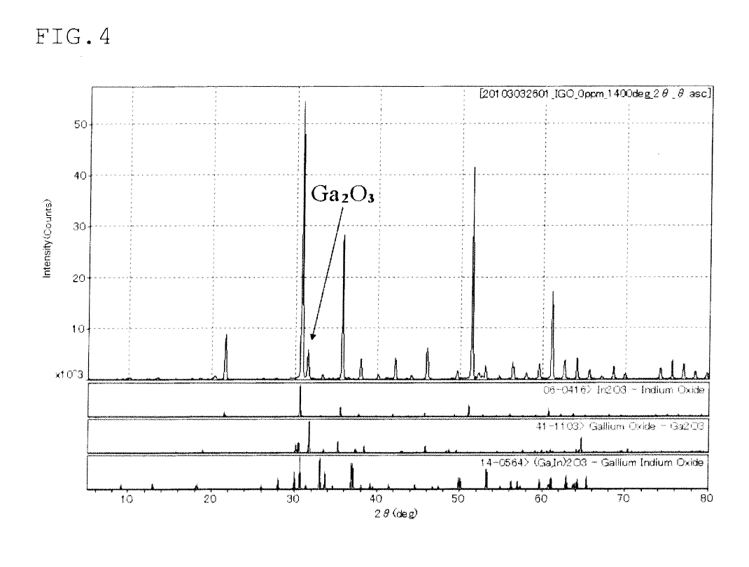

FIG. 4 shows a chart obtained by the X-ray diffraction of Comparative Example 1. In the X-ray diffraction chart, in addition to the bixbyite of In₂O₃, a Ga₂O₃ structure was also observed.

The targets of Comparative Examples 1 and 3 were cracked when bonding. The reason therefor is assumed to be that the target was inferior in thermal conductivity due to the presence of two different types of crystals in a mixture.

Transistors were formed and evaluated in the same manner as in Example 8 by using the target of Comparative Example 2 which did not crack. As a result, it was found that the semiconductor of Comparative Example 2 had a high conductivity due to the presence of a larger amount of tin, and had a threshold voltage of −10V, which was inferior to those of other semiconductors.

TABLE 2

| Comparative Examples | | 1 | 2 | 3 |
|---|---|---|---|---|
| Composition of | Composition | In—Ga—O | In—Ga—Sn—O | In—Ga—O |
| sintered body | Composition | In: 95 | In: 90 | In: 90 |
| | ratio (%) | Ga: 5 | Ga: 10 | Ga: 10 |
| | X/(In + Ga) | | Sn: 100000 ppm | |
| Firing | Temperature (° C.) | 1400 | 1400 | 1400 |
| | Time (h) | 20 | 20 | 20 |
| Evaluation | Bulk resistivity | 40 | 8 | 100 |
| of target | (mΩ · cm) | | | |
| | Density (cm⁻³) | 5 | 6.5 | 6.5 |
| | Occurrence of | Occurred | Did not occur | Occurred |
| | cracks | (discharge was | | (discharge was |
| | | impossible) | | impossible) |
| Sputtering | Ultimate | | 1.00E−04 | |
| conditions | pressure (Pa) | | | |
| | Sputtering | | 0.1 | |
| | pressure (Pa) | | | |
| | Introduction gas | | Ar, H₂O | |
| | Introduction ratio | | 98:2 | |
| | Power | | DC100 W | |
| XRD | As-depo | | Amorphous | |
| | Annealing | | 300° C. × 1 h | |
| | After annealing | | Crystalline | |
| FET | Mobility (cm²/Vs) | | 50 | |
| performance | Vth(V) | | −10(normally-on) | |
| | S value (V/dec) | | 5 | |

### INDUSTRIAL APPLICABILITY

The oxide sintered body of the invention can be used as a sputtering target. A thin film which is formed by using the sputtering target of the invention can be used in a thin film transistor.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification are incorporated herein by reference in its entirety.

1. An oxide sintered body comprising an oxide of indium (In), gallium (Ga), and positive trivalent and/or positive tetravalent metal X, wherein
the amount of the metal X relative to the total amount of In and Ga is 100 to 10000 ppm (weight).

2. The oxide sintered body according to claim 1, wherein the metal X is one or more selected from Sn, Zr, Ti, Ge and Hf.

3. The oxide sintered body according to claim 1, wherein the metal X comprises Sn.

4. The oxide sintered body according to any of claim 1, wherein an atomic ratio Ga/(Ga+In) is 0.005 to 0.15.

5. The oxide sintered body according to any of claim 1, wherein the bulk resistivity is 10 mΩcm or less.

6. The oxide sintered body according to any of claim 1, wherein the particle size of dispersed gallium is 1 μm or less.

7. The oxide sintered body according to any of claim 1, wherein gallium and metal X are dispersed in the solid-solution state in the bixbyite structure of In₂O₃.

8. A method for producing the oxide sintered body according to any of claim 1, comprising the steps of:
mixing indium compound powder having an average particle size of less than 2 μm, gallium compound powder having an average particle size of less than 2 μm and metal X compound powder having an average particle size of less than 2 μm such that the atomic ratio Ga/(In+Ga) becomes 0.001 to 0.10 and the amount of the metal X relative to the total amount of In and Ga becomes 100 to 10000 ppm;
shaping the mixture to prepare a shaped body; and
firing the shaped body at 1200 to 1600° C. for 2 to 96 hours.

9. The method for producing an oxide sintered body according to claim 8, wherein the firing is conducted in the atmosphere of oxygen or under pressure.

10. A sputtering target comprising the oxide sintered body according to any of claim 1.

11. An oxide thin film which is formed by using the sputtering target according to claim 10.

12. An oxide thin film comprising an oxide of indium (In), gallium (Ga) and positive trivalent and/or positive tetravalent metal X, wherein the amount of the metal X relative to the total amount of In and Ga is 100 to 10000 ppm (weight).

13. An oxide semiconductor device wherein an active layer comprises the oxide thin film according to claim 11.

14. An oxide semiconductor device wherein an active layer comprises the oxide thin film according to claim 12.
